(19) United States
(12) Patent Application Publication
(10) Pub. No.: US 2010/0275998 A1
(43) Pub. Date: Nov. 4, 2010

(54) LIGHT CONVERGING DEVICE HAVING COOLING ASSEMBLY AND RELATED SOLAR ENERGY CONVERTING SYSTEM

(75) Inventor: JEN-TSORNG CHANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/649,520

(22) Filed: Dec. 30, 2009

(30) Foreign Application Priority Data
Apr. 30, 2009 (CN) 200910301997.3

(51) Int. Cl. H01L 31/00; G02B 3/08

(52) U.S. Cl. 136/259; 359/742

(57) ABSTRACT

A exemplary light converging device includes a support, a supporting plate, a reflective Fresnel lens and a cooling assembly. The supporting plate is rotatably mounted on the support. The reflective Fresnel lens is fixedly mounted on the supporting plate. The cooling assembly is positioned between the reflective Fresnel lens and the supporting plate. The cooling assembly is thermally coupled to the reflective Fresnel lens and configured for cooling the reflective Fresnel lens.

### BACKGROUND

1. Technical Field

The present disclosure relates to light converging devices having cooling assemblies and related solar energy converting systems.

2. Description of Related Art

Due to the growing demand of clean energy, solar energy converting systems are widely used in recent years. In such a system, a light converging device is employed to converging sunlight onto a solar energy converting unit. This can increase a utilization rate of solar energy. However, solar energy also causes a Fresnel lens of the light converging device to heat. Thus, the Fresnel lens may be easily damaged or distorted.

Therefore, a light converging device having a cooling assembly and a solar energy converting system are desired.

### BRIEF DESCRIPTION OF THE DRAWINGS

FIG. 1 is an isometric and schematic view of a light converging device, according to a first exemplary embodiment.

FIG. 2 is a sectional view taken along line II-II of the light converging device of FIG. 1.

FIG. 3 is a sectional view of the light converging device, according to a second exemplary embodiment.

FIG. 4 is a sectional view of a solar energy converting system, according to a third exemplary embodiment.

### DETAILED DESCRIPTION

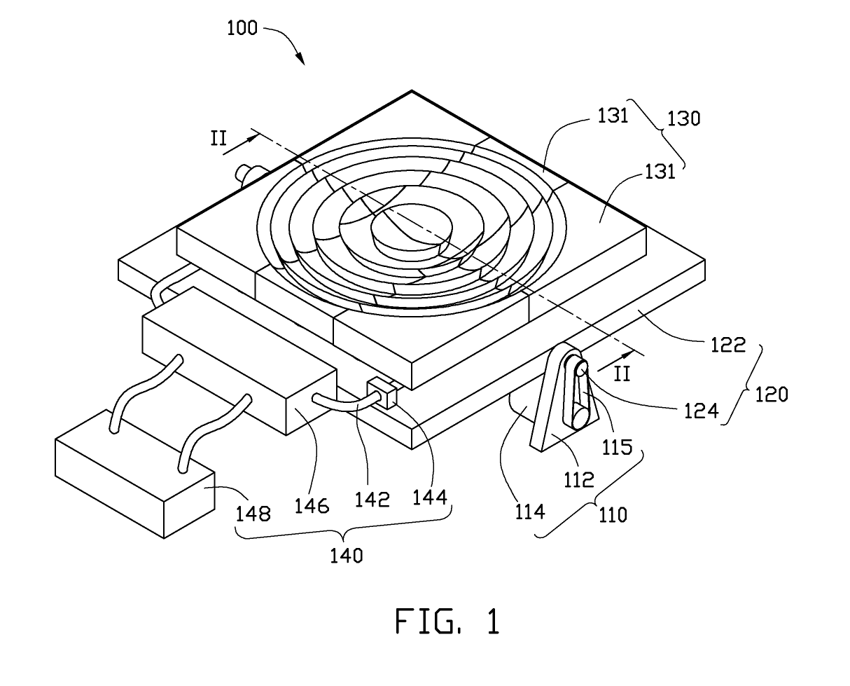

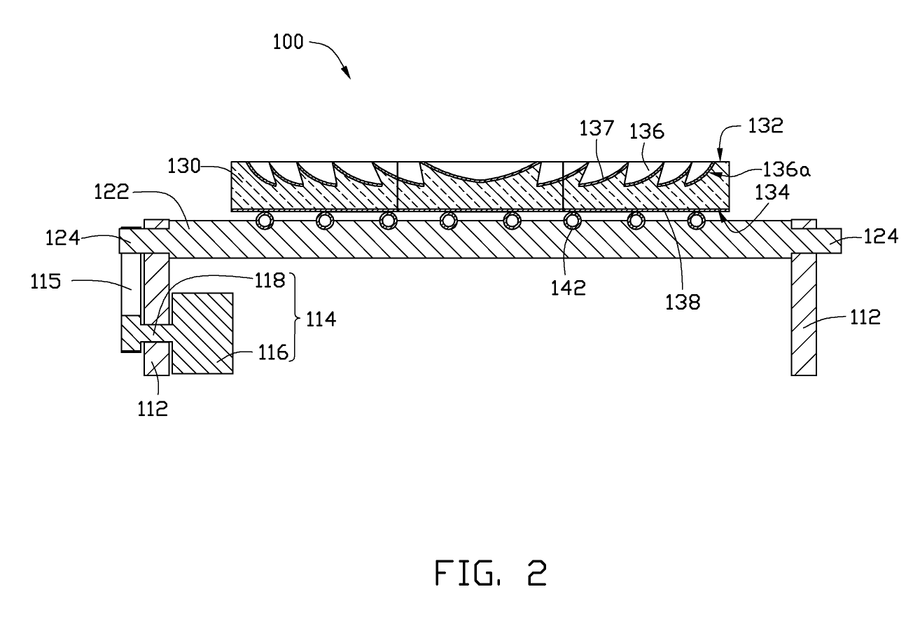

Referring to FIGS. 1 and 2, a light converging device 100, according to a first exemplar embodiment, includes a support 110, a supporting plate 120, a reflective Fresnel lens 130 and a cooling assembly 140.

The support 110 includes two bases 112, a motor 114 and a belt 115. Each of the bases 112 is substantially triangular-prism-shaped. The motor 114 includes a body 116 and a rotor 118. The rotor 118 is rotatably coupled to the body 116 and rotatably extends through one base 112.

The supporting plate 120 includes a plate body 122 and two rotating shafts 124. The two rotating shafts 124 extend from two opposite sides of the plate body 122 and rotatably extend through the two bases 112. Therefore, the two opposite ends of the supporting plate 120 are pivotedly coupled to the two bases 112 using the two rotating shafts 124. The belt 115 wraps round a distal end of the rotor 118 and a distal end of one rotating shaft 124 to transmit driving force of the motor 114 to rotate the supporting plate 120.

The reflective Fresnel lens 130 is fixedly mounted on the plate body 122. The reflective Fresnel lens 130 is single-focus-point and may be made from plastic by injection molding. The reflective Fresnel lens 130 comprises a plurality of sub lenses 131. The plurality of sub lenses 131 are arranged in a 2×3 array in this embodiment. Therefore, when the motor 114 is activated, the motor 114 can drive the supporting plate 120 to rotate about the two rotating shafts 124. The reflective Fresnel lens 130 can be redirected accordingly.

The reflective Fresnel lens 130 includes an upper surface 132 and a lower surface 134. The upper surface 132 faces away from the plate body 122 and the lower surface 134 faces the plate body 122. A plurality of grooves 136 are defined in the upper surface 132. The grooves 136 are arranged in concentric circle from a center of the reflective Fresnel lens 130. A cross section of the groove 136 along line II-II as illustrated in FIG. 1 is substantially V-shaped (see FIG. 2). The reflective Fresnel lens 130 further includes a plurality of inwardly curved surfaces 136a in the grooves 136. The inwardly curved surface 136a is substantially parabolic and is configured for converging light. Antireflection layers 137 are formed on the inwardly curved surfaces 136a. The antireflection layer 137 may be a wide-band antireflection layer covering bands of ultraviolet light, visible light, and far infrared light. Incident light on the inwardly curved surfaces 136a propagates into the reflective Fresnel lens 130. Optical performance of the reflective Fresnel lens 130 can be determined according to need.

A reflective layer 138 is formed on the lower surface 134. A material of the reflective layer 138 may be aluminum, gold, silver, or alloy. The reflective layer 138 may be formed on the lower surface 134 by a vapor deposition process or a sputtering process. Light passing through the reflective Fresnel lens 130 is reflected back to the reflective Fresnel lens 130 and then is converged by the reflective Fresnel lens 130.

The cooling assembly 140 is configured for cooling the reflective Fresnel lens 130. The cooling assembly 140 includes a heat sink pipe 142, a temperature sensor 144, a controller 146 and a cooling device 148. The heat sink pipe 142 is arranged between the plate body 122 and the reflective Fresnel lens 130 and is thermally coupled to the reflective Fresnel lens 130. The heat sink pipe 142 may be made from copper, gold, or stainless steel. The heat sink pipe 142 is filled with coolant. The coolant may be liquid, such as water or oil.

The temperature sensor 144 is configured for measuring a temperature of the coolant in the heat sink pipe 142. The controller 146 is configured for driving the coolant to flow from the heat sink pipe 142 into the cooling device 148 according to the temperature of the coolant. In detail, a predetermined temperature of the coolant is set in the controller 146. When the temperature of the coolant is greater than the predetermined temperature, the controller 146 drives the coolant from the heat sink pipe 142 into the cooling device 148. Therefore, the coolant of high temperature in the heat sink pipe 142 between the reflective Fresnel lens 130 and the plate body 122 enters the cooling device 148. The cooling device 148 is configured for cooling the coolant inform the heat sink pipe 142. The cooling device 148 may include heat sinks and/or fans to cool the coolant from the heat sink pipe 142. The predetermined temperature may be set according to a practical use. The controller 146 may include a pump(s) to regulate circulation of the liquid coolant in the heat sink pipe 142.

When in use, the reflective Fresnel lens 130 heats up due to solar energy. Heat generated by the reflective Fresnel lens 130 is transferred to the coolant in the heat sink pipe 142 between the reflective Fresnel lens 130 and the plate body 122. The temperature of the coolant in the heat sink pipe 142 is detected by the temperature sensor 144. The controller 146 drives the coolant from the heat sink pipe 142 into the cooling device 148 if the temperature of the coolant is greater than the predetermined temperature. Then, the coolant of high temperature enters the cooling device 148 and is cooled by the cooling device 148. The cooled coolant is driven by the controller 148 to dissipate heat generated by the reflective Fresnel lens 130. Therefore, the reflective Fresnel lens 130 can be cooled down and a usage life of the reflective Fresnel lens 130 can be prolonged.

Furthermore, because the reflective Fresnel lens 130 can be redirected by the motor 114, the reflective Fresnel lens 130 can remain facing the sun directly to converge sunlight at different time of the day. This increases a received solar energy from the sun.

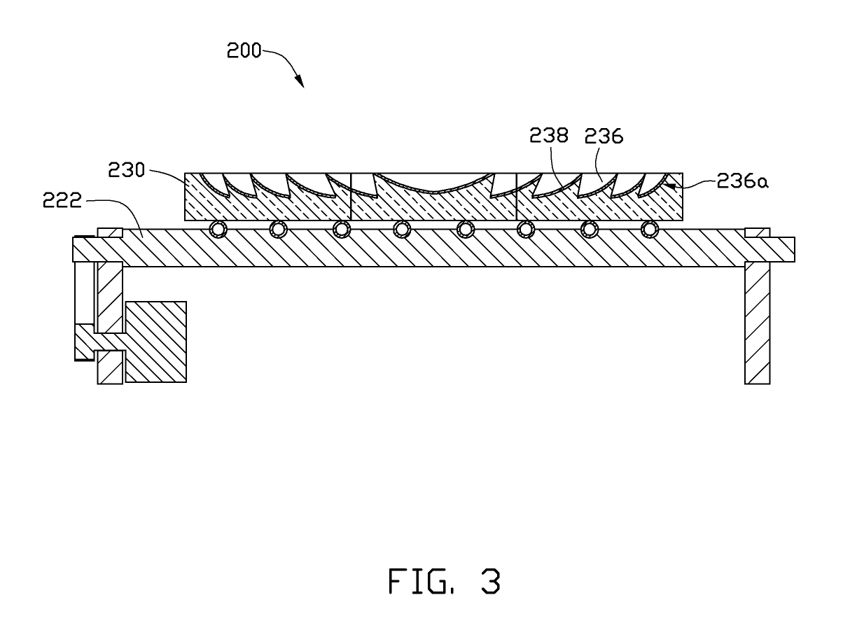

Referring to FIG. 3, a light converging device 200, according to a second exemplary embodiment, is shown. Differences between the light converging device 200 and the light converging device 100 of the first exemplary embodiment are that in the light converging device 200, antireflection layers are omitted and positions of reflective layers 238 are different.

In this embodiment, the reflective layers 238 are formed on the inwardly curved surfaces 236a of the plate body 222 in the grooves 236. When the light strikes on the inwardly curved surfaces 236a, the light is reflected by the reflective layers 238 and then is converged by the reflective Fresnel lens 230.

Advantages of the light converging device 200 of this embodiment are similar to those of the light converging device 100 of the first embodiment. Furthermore, because the antireflection layers are omitted, manufacturing of the light converging device 200 costs less time.

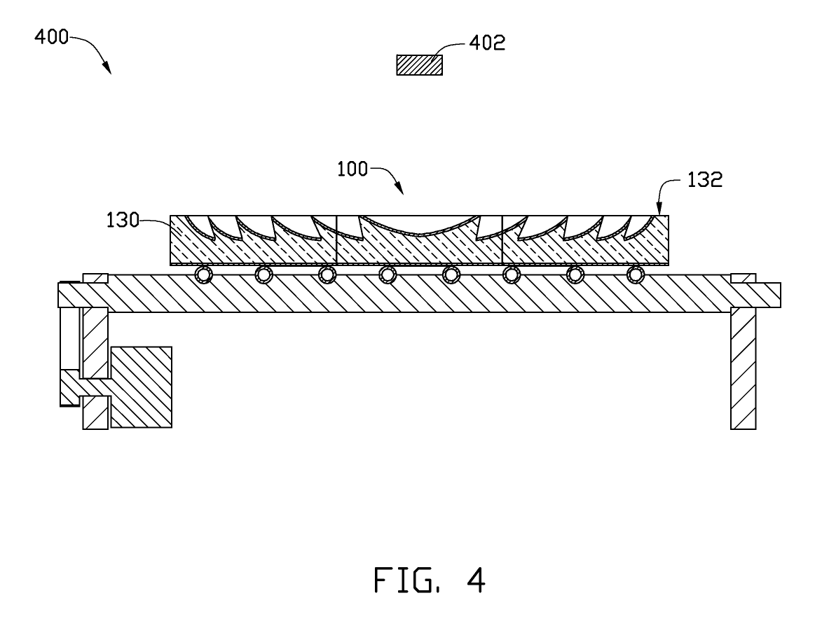

Referring to FIG. 4, a solar energy converting system 400, according to a third exemplary embodiment, includes a solar energy converting unit 402 and the light converting device 100 of the first exemplary embodiment.

The solar energy converting unit 402 is configured for converting solar energy into electrical energy. The solar energy converting unit 402 faces the upper surface 132 of the reflective Fresnel lens 130. Material of the solar energy converting unit 402 may be gallium arsenide, gallium aluminum arsenide, or indium phosphide. The solar energy converting unit 402 may be fixed in the solar energy converting system 400 by some suitable fixing means and can move together with the reflective Fresnel lens 130. It is to be understood that when the reflective Fresnel lens 130 is redirected, the solar energy converting unit 402 moves together with the reflective Fresnel lens 130 so that the reflective Fresnel lens 130 can converges light on the solar energy converting unit 402 even if the reflective Fresnel lens 130 moves.

When in use, sunlight is converged by the reflective Fresnel lens 130 to strike the solar energy converting unit 402. The solar energy converting unit 402 converts the converged sunlight into electrical energy.

It can be understood that in other alternative embodiment, the solar energy converting system includes the light converging device 200 of the second exemplar embodiment instead of the light converging device 100.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light converging device, comprising:
a support;
a supporting plate rotatably mounted on the support;
a reflective Fresnel lens fixedly mounted on the supporting plate; and
a cooling assembly positioned between the reflective Fresnel lens and the supporting plate, the cooling assembly thermally coupled to the reflective Fresnel lens and configured for cooling the reflective Fresnel lens.

2. The light converging device of claim 1, wherein the support comprises two bases, a motor and a belt, opposite ends of the supporting plate pivotedly coupled to the two bases, the motor configured for driving the supporting plate to rotate, the belt configured for transmitting drive of the motor to the supporting plate.

3. The light converging device of claim 2, wherein each of the two bases is substantially triangular-prism-shaped.

4. The light converging device of claim 2, wherein the supporting plate comprises a plate body and two rotating shafts extending from two opposite sides of the plate body and rotatably extending through the two bases, the reflective Fresnel lens fixedly mounted on the plate body.

5. The light converging device of claim 4, wherein the reflective Fresnel lens comprises an upper surface facing away from the plate body, and a lower surface facing the plate body.

6. The light converging device of claim 5, wherein the reflective Fresnel lens includes a plurality of grooves defined in the upper surface and a plurality of inwardly curved surfaces in the grooves.

7. The light converging device of claim 6, wherein the reflective Fresnel lens further comprises a plurality of antireflection layers and a reflective layer, the antireflective layers formed on the inwardly curved surfaces, and the reflective layer formed on the lower surface.

8. The light converging device of claim 7, wherein the reflective layer is comprised of a material selected from the group consisting of aluminum, gold, silver and alloy thereof.

9. The light converging device of claim 1, wherein the reflective Fresnel lens comprises a plurality of sub lenses arranged in an array.

10. The light converging device of claim 6, wherein the reflective Fresnel lens further comprises a plurality of reflective layers formed on the inwardly curved surfaces.

11. The light converging device of claim 1, wherein the cooling assembly comprises a heat sink pipe, a temperature sensor, a controller and a cooling device, the heat sink pipe arranged between the supporting plate and the reflective Fresnel lens and configured for receiving coolant, the temperature sensor configured for detecting a temperature of the coolant in the heat sink pipe, the controller configured for driving the coolant to flow from the heat sink pipe into the cooling device according to the detected temperature of the coolant, the cooling device configured for cooling the coolant in the heat sink pipe.

12. A solar energy converting system, comprising:
a solar energy converting unit configured for converting solar energy into electrical energy; and
a light converging device, comprising:
a support;
a supporting plate rotatably mounted on the support;
a reflective Fresnel lens fixedly mounted on the supporting plate and configured for converging light onto the solar energy converting unit; and
a cooling assembly positioned between the reflective Fresnel lens and the supporting plate, the cooling assembly thermally coupled to the reflective Fresnel lens and configured for cooling the reflective Fresnel lens.

13. The solar energy converting system of claim 12, wherein the support comprises two bases, a motor and a belt, opposite ends of the supporting plate pivotedly coupled to the two bases, the motor configured for driving the supporting plate to rotate, the belt configured for transmitting drive of the motor to the supporting plate.

14. The solar energy converting system of claim 13, wherein the supporting plate comprises a plate body and two rotating shafts extending from two opposite sides of the plate body and rotatably extending through the two bases, the reflective Fresnel lens fixedly mounted on the plate body.

15. The solar energy converting system of claim 14, wherein the reflective Fresnel lens comprises an upper surface facing away from the plate body, and a lower surface facing the plate body.

16. The solar energy converting system of claim 15, wherein the reflective Fresnel lens includes a plurality of grooves defined in the upper surface and a plurality of inwardly curved surfaces in the grooves.

17. The solar energy converting system of claim 16, wherein the reflective Fresnel lens further comprises a plurality of antireflection layers and a reflective layer, the antireflective layers formed on the inwardly curved surfaces, and the reflective layer formed on the lower surface.

18. The solar energy converting system of claim 16, wherein the reflective Fresnel lens further comprises a plurality of reflective layers formed on the inwardly curved surfaces.

19. The solar energy converting system of claim 12, wherein the cooling assembly comprises a heat sink pipe, a temperature sensor, a controller and a cooling device, the heat sink pipe arranged between the supporting plate and the reflective Fresnel lens and configured for receiving coolant, the temperature sensor configured for detecting a temperature of the coolant in the heat sink pipe, the controller configured for driving the coolant to flow from the heat sink pipe into the cooling device according to the detected temperature of the coolant, the cooling device configured for cooling the coolant in the heat sink pipe.
